(19) United States
(12) Patent Application Publication
(10) Pub. No.: US 2023/0044479 A1
(43) Pub. Date: Feb. 9, 2023

(54) RETENTION SYSTEM FOR LIQUID COOLING SYSTEMS OF COMPUTERS

(71) Applicant: Asetek Danmark A/S, Aalborg East (DK)

(72) Inventor: Lars Brinkmann Fuglsang, Aalborg (DK)

(73) Assignee: Asetek Danmark A/S, Aalborg East (DK)

(21) Appl. No.: 17/444,726

(22) Filed: Aug. 9, 2021

(51) Int. Cl. H05K 7/20; G06F 1/20

(52) U.S. Cl. CPC H05K 7/20254; G06F 1/20

(57) ABSTRACT

A system for cooling computer hardware includes a heat exchanger having a computer hardware contact surface configured to be in thermal contact with the computer hardware on a first side and to be in thermal contact with a cooling liquid on a second side, the second side being opposite to the first side. The system also includes a bracket configured to removably clamp the heat exchangerto the computer hardware.

### BACKGROUND

### Field of the Invention

Systems consistent with the present invention generally relate to a liquid cooling of a heat generating element in a computing system such as a CPU or a GPU. More particularly, systems consistent with the invention relate to the efficient attaching of a liquid cooling system to a heat generating element in a computing system.

### Discussion of the Related Art

Cooling systems for a central processing unit (CPU), a graphic processing unit (GPU) or other processing unit of a computer system are widely used to remove heat created by the processing unit.

During operation of a computer, the heat created inside the processing unit must be carried away fast and efficiently, keeping the temperature within the design range specified by the manufacturer in order to avoid heat related damage from occurring to the processing unit.

Efforts to prevent such heat related damage from occurring make use of various conventional processing unit cooling methods/systems. The most commonly used conventional cooling system utilizes an air-cooling arrangement, wherein a heat sink in thermal contact with the processing unit transports the heataway from the processing unit and either passive airflow or active airflow via a fan mounted on top of the heat sink that removes heat from the heat sink by blowing airthrough the segments (i.e., fins) of the heatsink.

Another conventional cooling system utilizes cooling liquid to cool the processing unit by circulating the cooling liquid inside a closed system via a pumping unit. Such a closed system also includes a heat exchanger past which the cooling liquid is circulated to allow heat to exit the system. A typical liquid-cooling system is provided as an integrated unit having both the cooling surface and the pump for circulating the cooling liquid. Liquid cooling systems have certain advantages over air-cooling arrangements. For example, a liquid-cooling system is more efficientthan an air-cooling system and tends to generate less noise. These advantages are making liquid cooling systems more and more popular especially given that increased cooling demands are occurring as the size and performance of processing units continue to increase (which also increases the heat generated from such processing units).

However, the increased demand for liquid cooling arrangements has broughtto light certain disadvantages of conventional liquid cooling systems. For example, since conventional liquid cooling systems are designed to accommodate very specific processor configurations, multiple different types of liquid cooling systems must be created to accommodate different processing units because the size of different processing units (and consequently the heat generated by such processing units) vary over a wide range. Since multiple different liquid cooling systems with different capacities and varying sizes are necessary to provide efficient cooling to the different processing units underconventional designs, (i) consumers are forced purchase entirely new liquid cooling systems when their processor configurations change.

In view of the foregoing, it is desirable to reduce the need for replacing liquid cooling systems. For example, there is a need for an improved system to provide liquid cooling to consumers in a mannerthat is less likely to need replacement.

### SUMMARY OF THE INVENTION

In contrast to the above described conventional liquid cooling systems, an improved cooling system reduces the need for replacement by allowing the system to be disconnected from one processor configuration and mounted to another processor configuration in a mannerthat provides close contact in an easy and reliable manner. Since the improved cooling system can be easily detached from processing units and reused on other processing units, consumers avoid having to purchase an additional liquid cooling system when they decide to upgrade from one computer configuration to another.

A system for cooling computer hardware includes a heat exchanger including a computer hardware contact surface configured to be in thermal contact with the computer hardware on a first side and to be in thermal contact with a cooling liquid on a second side, the second side being opposite to the first side, the heat exchanger defining at least two bracket pockets; and at least two substantially planar elongated brackets, each of the at least two brackets being configured to, (i) at a first end, partially insert into each of the at least two bracket pockets and (ii) at a second end clamp to the computer hardware; wherein, when each of the at least two brackets are configured to (i) partially insert into each of the at least two bracket pockets at the first end and (ii) clamp to the computer hardware at the second end, the computer hardware contact surface is in tight contact with the computer hardware.

A system for cooling computer hardware includes a heat exchanger including a computer hardware contact surface configured to be in thermal contact with the computer hardware on a first side and to be in thermal contact with a cooling liquid on a second side, the second side being opposite to the first side; and a bracket configured to removably clamp the heat exchangerto the computer hardware.

### BRIEF DESCRIPTION OF THE DRAWINGS

The accompanying drawings, which are incorporated in and constitute a part of this disclosure, illustrate various embodiments and aspects of the present invention. In the drawings:

FIG. 1 shows a liquid cooling system in accordance with disclosed embodiments;

FIG. 2A shows a top view of the mounting of a retention bracket elementafter insertion in accordance with a first embodiment;

FIG. 2B shows a top view of the mounting of a retention bracket element prior to insertion in accordance with a first embodiment;

FIG. 3A shows a close up view of the mounting of FIG. 2A;

FIG. 3B shows a close up view of the mounting of FIG. 2B

FIG. 4 shows a bottom part of the liquid cooling system;

FIG. 5A shows a top view of the mounting of a retention bracket element prior to insertion in accordance with a second embodiment;

FIG. 5B shows a perspective view of the mounting of a retention bracket element prior to insertion in accordance with a second embodiment; and

FIG. 5C shows a top view of the mounting of a retention bracket element after insertion in accordance with a second embodiment.

### DETAILED DESCRIPTION

The following detailed description refers to the accompanying drawings. Wherever possible, the same reference numbers are used in the drawings and in the following description to refer to the same or similar parts. While several exemplary embodiments and features of the invention are described herein, modifications, adaptations, and other implementations are possible without departing from the spirit and scope of the invention. For example, substitutions, additions, or modifications may be made to the components illustrated in the drawings, and the exemplary methods described herein may be modified by substituting, reordering, or adding steps to the disclosed methods. Accordingly, the following detailed description does not limit the invention. Instead, the proper scope of the invention is defined by the appended claims.

Systems consistent with the present invention generally relate to a liquid cooling of a heat generating element in a computing system such as a CPU or a GPU.

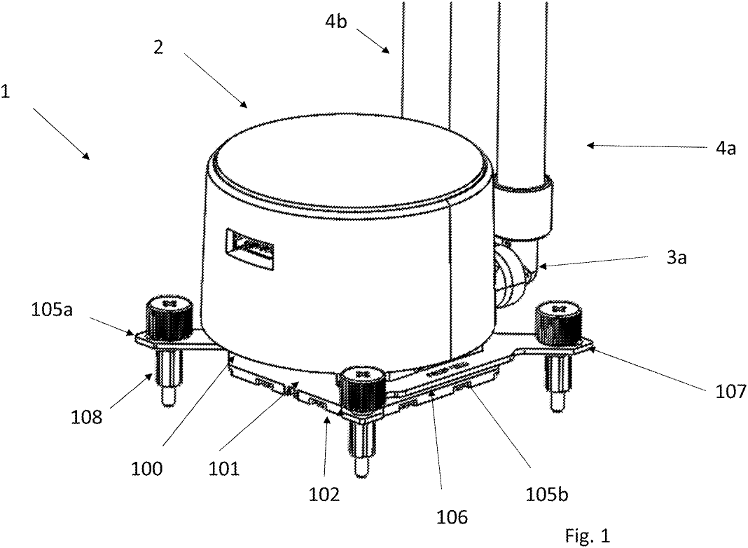

FIG. 1 shows a liquid cooling system 1 for cooling a surface of a heat generating element (not shown) in a computing system such as a CPU or a GPU.

The heat generating element is an element which generates heat during operation and is typically mounted in the motherboard or main board of a computing system. In this context, the heat generating element may include more than the CPU or GPU itself, and may also include neighbouring areas (e.g., attachments). One surface of the heat generating element (i.e., an exposed surface) is in contact with a cooling surface 102 of the cooling system 1 and this exposed surface is denoted as the upper surface of the heat generating element.

The liguid cooling system 1 includes a pump inside a pump lid 2 and mounted is on a heat exchanger 100. The liguid cooling system 1 also includes connections 3a, 3b for liquid which is transported in tubes 4a, 4b.

The heat exchanger 100 includes the cold plate housing 101 which serves to cool the cold plate 102. During operation, the cold plate 102 is in contact with the heat generating element (not shown) to be cooled. The cold plate housing 101 and the cold plate 102 forms the cooling surface of the cooling system 1.

The liguid cooling system 1 is attached to a heat generating element by means of retention brackets 105a, 105b. Each retention bracket 105 comprises a first elongated end 106 connected with the cold plate housing 101 and an opposite second end 107 with clamp 108 for clamping the retention bracket 105 to the heat generating element.

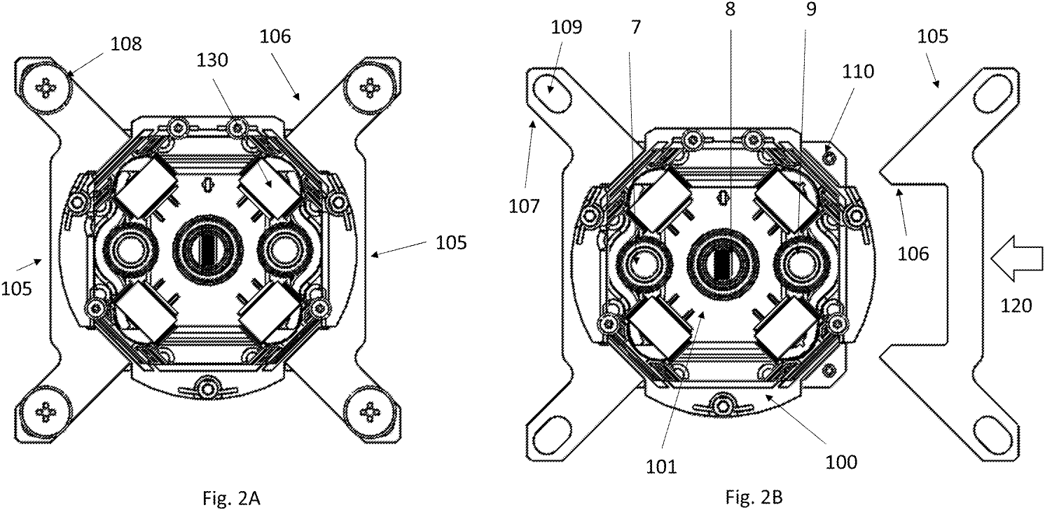

FIGS. 2A-B show a way of mounting a retention bracket 105 in the housing 101 of the liquid cooling system 1. In FIGS. 2A-B, the pump lid 2 and the pumping system are not shown. The heat exchanger 100 includes the cold plate housing 101 and the cold plate 102 below the cold plate housing 101 (the cold plate 102 is not visible in FIG. 2). The cold plate housing 101 comprises openings 7, 8, 9 for circulating liquid to cool the cold plate 102. During operation the openings 7, 8, 9 are connected with a not shown pump.

The retention bracket 105 illustrated in FIGS. 2A-B includes two elongated ends 106 to be mounted in the support areas 110 of the housing 101. Thus, in this embodiment the liquid cooling system 1 will be mounted to the heat generating element by means of two retention brackets 105. As can be seen in FIGS. 2A-B, the retention bracket 105 is moved in the direction indicated by arrow 120 to be guided into the support areas 110 in the housing 101. In the support areas 110 the elongated ends 106 will engage with pockets 111 (not visible in the figure) and may be fixed in the pockets 111 via, for example, magnets 130.

Consequently, in this embodiment the retention brackets 105 are made from a metallic material which is magnetic. Moreover, in the second opposite ends 107, the retention bracket 105 comprises an oblong opening 109 which can be used for adjustment of the attachment of the retention bracket 105 to a heat generating element via a screw 108.

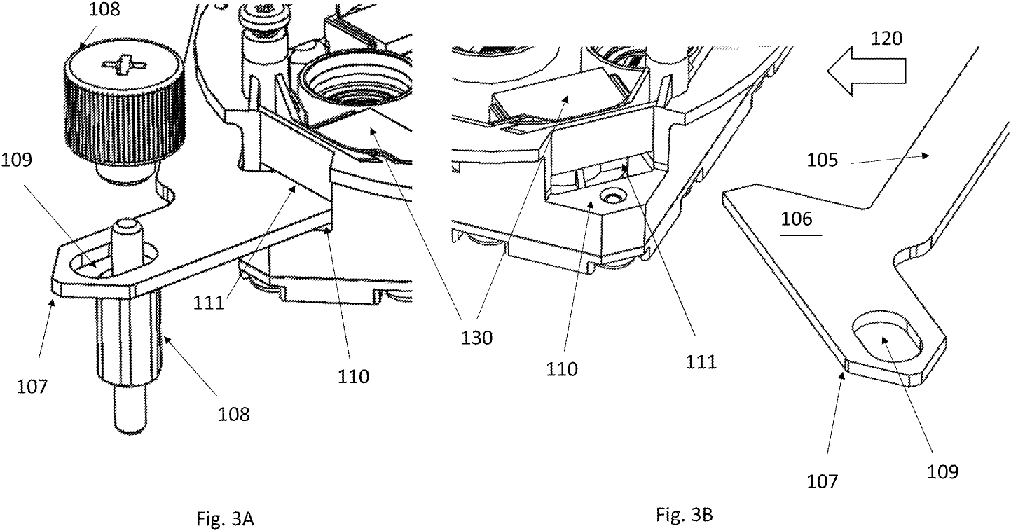

FIGS. 3A-B show close up details of the mounting in FIGS. 2A-B. FIGS. 3A-B illustrates how the metallic retention bracket 105 by movement in the direction indicated by arrow 120 is guided into the support area 110 and pocket 111 in the housing 101. In the pocket 111 first elongated end 106 of the retention bracket 105 is kept in fixed position via magnet 130. The second opposite end 107 of the retention bracket 105 can be fixed to the heat generating element via the oblong opening 109 and a screw 108 adapted for engagement with a hole in the heat generating element.

In the embodiment shown in FIGS. 3A-B the pocket 111 is formed by the support area 110, the housing 101, and the magnet 130. In other embodiments the pockets may be formed mainly in the housing 101.

As shown in FIGS. 3A-B the retention bracket 105 is moved towards the supporting area 110 and the pocket 111. The supporting area 110 is an area or platform which the first elongated end 106 of the retention bracket 105 can engage with to facilitate insertion into the pocket 111. When the first elongated end 106 of the retention bracket reaches the pocket 111 it is pushed into the pocket 111 until it reaches a stop inside the pocket 111. In this embodiment the stop is constituted by the magnet 130 and the first elongated end 106 will be kept in a fixed position inside the pocket 111 via the magnet 130. Subsequently, the retention bracket 105 can be attached to a heat generating element via the screw 108 through the oblong opening 109.

When the four retention brackets 105 (see FIGS. 2A-B) are positioned with a part of the first elongated ends 106 located in a fixed position in the pockets 111 and the second opposite ends 107 attached to a heat generating element, the fixation of the first elongated ends 106 in the pockets 111 ensures an efficient clamping such that the forces in the contact area between the cooling plate and heat generating element are sufficient to provide an efficient heat transfer.

A retainer system of brackets 105 is constructed such that a reliable and durable attachment is established between the housing 101 and the heat generating element, allowing a good and close physical contact between the cooling surface 102 and the surface of the heat generating element, such that the cooling surface 102 can transport heat away from the surface of the heat generating element. This reliable and durable attachment is due to the pockets 111 which allow the retention brackets 105 to provide an increased tension in the system 1 which improves the clamping forces.

The pockets 111 in the support areas of the housing 101 are preferably recesses adapted such that they can receive the first elongated ends 106 of the retention brackets 105 and via the engagement between the pockets 111 and the elongated ends 106 keep the housing 101 fixed in respect of the heat generating element. Depending on the size of the retention brackets 105, the pockets 111 have a depth in the range of about 1 mm to about 100 mm, such as a depth in the range of about 2 mm to about 80 mm. In embodiments where the retention brackets extend through the housing 101, the pockets are shaped like a tunnel in the housing 101. The height of the pocket 111 may be in the range of 1 to 10 mm, such as in the range 2 mm to 6 mm. The width of the pocket 111 may be in the range 2 mm to 100 mm such as in the range 5 mm to 50 mm. Depending of the shape of the first elongated end 106, (i.e., the first elongated end 106 may, for example, taper with the width of the pocket 111 decreasing towards the bottom of the pocket 111.

The depth of the pocket 111 is the extension of the pocket 111 in the direction of which the first elongated end 106 is inserted. In some embodiments the pockets 111 may extend through the entire housing 101.

The first elongated ends 106 of the retention brackets 105 are inserted into the pockets 111 in a length corresponding to the depth of the pockets 111. A stop such as an end wall may be provided in the pockets 111. When the retention brackets 105 are attached to the heat generating elementat their second ends 107, the engagement between the pockets 111 and the elongated ends 105 makes it possible to achieve a certain tension in the retention bracket whereby an efficient clamping of the housing 101 to the heat generating element via the retention bracket 105 can be achieved.

The housing 101 of the cooling system 1 preferably includes an even number of support areas and pockets 111, such as two, four, six or more support areas and pockets 111. Preferably the housing comprises four support areas and four pockets 111 adapted for housing four first elongated ends 106.

In an embodiment of the liquid cooling system 1, the system 1 includes two retention bracket elements 105. Each retention bracket 105 comprises two first elongated ends 106 for insertion into the pockets 111 in the housing 101.

In an alternative embodiment the system 1 includes four retention bracket elements 105. Thus, if the housing comprises four support areas with pockets 111, one retention bracket 105 is placed in each pocket.

The elongated ends 106 of the retention brackets 105 may be retained in the pockets 111 of the support areas in several ways including via magnets. In another embodiment, the first elongated ends 106 of the retention bracket elements 105 are retained in the pockets via balls and springs (i.e., spring-loaded detents). The balls may be connected with the support area by means of the spring and the balls may be located in grooves in the elongated ends of the retention bracket elements such that the balls and the grooves engage to maintain the elongated ends 106 fixed in the pockets 111 in the housing 101 of the cooling system 1. In yet another embodiment, the first elongated ends 106 of the retention bracket elements 105 are retained in the pockets 111 by, for example snap-fit connectors. The snap-fit connectors are adapted to press against a part of the first elongated ends 106 and fix them in the pockets 111. The first elongated ends 106 of the retention bracket elements 105 may also be retained in the pockets via glue, screws or pins.

In an embodiment of the liquid cooling system 1, the second end 107 of the retention bracket elements 105 are clamped to the heat generating element via nuts such as thumb nuts. However, glue, screws or pins may also be used.

The retention bracket elements 105 should be able to keep the cooling surface 102 of the liquid cooling system 1 in physical contact with a surface of the heat generating elementto transfer heat. Accordingly, the retention bracket elements 105 should have sufficient strength. Thus, in an embodiment the retention bracket elements 105 are manufactured from rigid material selected from metallic material such as steel, brass or copper, polymer material such as polyethylene, polystyrene, polyurethane, polyvinyl chloride.

The thickness and the size of the retention bracket elements 105 may vary depending on the size of the cooling system 1, which depends on the size of the heat geniting element. The thickness of the retention bracket elements 105 may be in the range of 1 to 10 mm, such as in the range 2 mm to 6 mm. The length and width of the retention bracket elements 105 may vary between 2 and 8 cm. The width of the first elongated end 106 may be in the range 2 mm to 100 mm such as in the range 5 mm to 50 mm.

As the retention bracket elements 105 should have sufficient strength, the retention bracket elements 105 may have a Youngs modulus of at least 2 GPa, such as at least 5 GPa, or as at least 20 GPa when measured according to ASTM E111-17.

To obtain an efficientcooling by the liquid cooling system 1 the cooling surface 102 is in thermal contact with the upper surface of the heat generating element and is pressed towards the upper surface of the heat generating element with a force of at least 2 Pa.

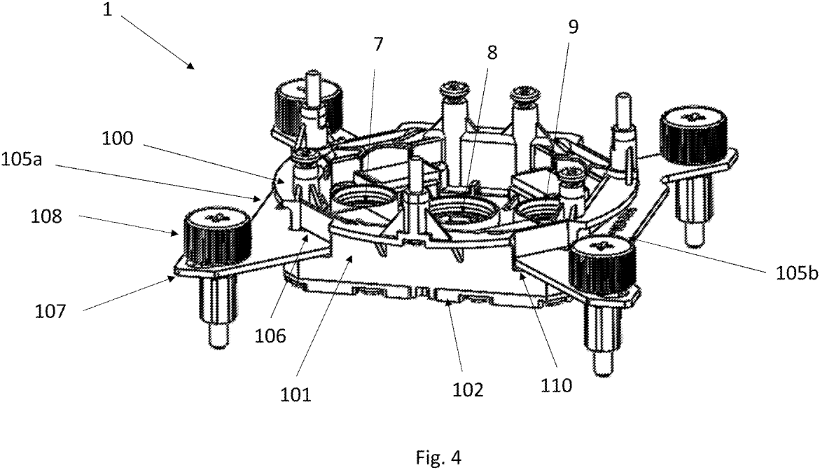

FIG. 4 shows the bottom part of the liquid cooling system 1 without pump lid 2 mounted. The heat exchanger 100 includes the cold plate housing 101 and the cold plate 102 below the cold plate housing 101. The cold plate housing 101 includes openings 7, 8, 9 for circulating liquid to cool the cold plate 102. During operation the openings 7, 8, 9 are connected with a not shown pump.

The first elongated ends 106 of the retention brackets 105a, 105b are mounted in pockets in the support areas 110 in the cold plate housing 101. The pockets are not visible in the FIG. 4 as a certain part of the first elongated ends 106 are housed in the pockets. In the second opposite end 107, a screw 108 can be used for attaching the retention brackets 105a, 105b to a heat generating element.

Thus, the retention bracket element 105a is mounted via the support areas 110 in the cold plate housing 101. The retention brackets 105a and 105b comprise two elongated ends 106 to be mounted in the support areas 110 of the housing 101. The elongated ends 106 are mounted in the pockets in the support area 110 and when the elongated ends 106 are mounted in the support areas 110 the liquid cooling system can be attached to a heat generating element via the screws 108 in the second opposite end 107.

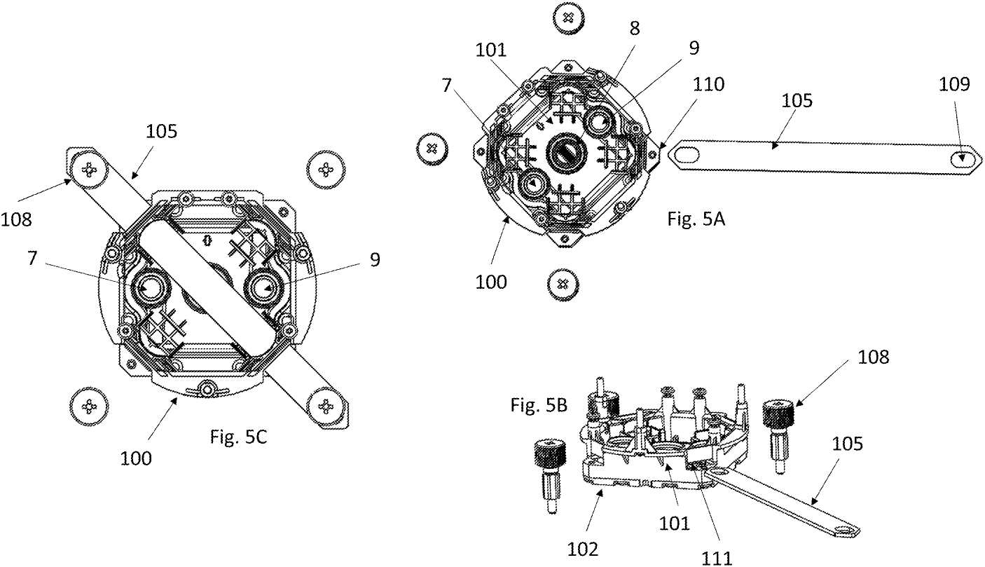

FIGS. 5A-C shows an embodiment where the brackets extend through the frame 100 and the cold plate housing 101, such that the housing 101 can be attached to the heat generating element by means of two crossing brackets 105. Each bracket 105 has an elongated shape and a length longerthatthe diameter of the cross-section of the cold plate housing 101.

Due to the through going brackets 105 the cold plate housing 101 includes only two openings 7 and 9 for circulating cooling liquid, one opening serves as inlet and the other opening serves as outlet for cooling liquid. Thus, in this embodiment the center opening 8 is blocked.

FIGS. 5A and 5B show the situation where the elongated bracket 105 is to be mounted in the housing 101. The bracket 105 is moved to the support area 110 and into the pocket 111 in the heat exchanger 100.

FIG. 5C shows the bracket 105 fully mounted in the housing 101. The bracket 105 can be attached to a heat generating element via screws 108. Another bracket (not shown) is mounted perpendicularto first bracket 105 thereby forming a cross in the housing 101.

The foregoing description has been presented for purposes of illustration. It is not exhaustive and does not limit the invention to the precise forms or embodiments disclosed. Modifications and adaptations of the invention will be apparent to those skilled in the art from consideration of the specification and practice of the disclosed embodiments of the invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system for cooling computer hardware comprising:
a heat exchanger including a computer hardware contact surface configured to be in thermal contact with the computer hardware on a first side and to be in thermal contact with a cooling liquid on a second side, the second side being opposite to the first side, the heat exchangerdefining at least two bracket pockets; and
at least two substantially planar elongated brackets, each of the at least two brackets being configured to, (i) at a first end, partially insert into each of the at least two bracket pockets and (ii) at a second end clamp to the computer hardware;
wherein, when each of the at least two brackets are configured to (i) partially insert into each of the at least two bracket pockets at the first end and (ii) clamp to the computer hardware at the second end, the computer hardware contact surface is in tight contact with the computer hardware.

2. The system of claim 1:
wherein the at least two brackets are two brackets; and
wherein the two brackets are attached to each other in a linear arrangement with each of the two brackets facing each other at the first end.

3. The system of claim 2, wherein the two brackets form a monolithic structure.

4. The system of claim 1:
wherein the at least two brackets are four brackets;
wherein a first two brackets of the fourbrackets are attached to each other in a linear arrangement with each of the first two brackets facing each other at the first end; and
wherein a second two brackets of the four brackets are attached to each other in a linear arrangement with each of the second two brackets facing each other at the first end.

4. The system of claim 3, wherein the first two brackets and the second two brackets each form a monolithic structure.

5. The system of claim 3, wherein when the four brackets are partially inserted into the at least two bracket pockets, the first two brackets are substantially orthogonal to the second two brackets.

6. The system of claim 1:
wherein the at least two brackets are four brackets;
wherein a first two brackets of the four brackets are attached to each other in a su bstantially orthogonal arrangement with each of the first two brackets connected to each other by a first bridge that is attached to each of the first two brackets between the first end and the second end; and
wherein a second two brackets of the fourbrackets are attached to each other in a substantially orthogonal arrangement with each of the second two brackets connected to each other by a second bridge that is attached to each of the second two brackets between the first end and the second end.

7. The system of claim 6, wherein the first two brackets and the second two brackets each form a monolithic structure.

8. The system of claim 1, wherein each of the at least two bracket pockets each have an opening height of 1 to 10 mm and an opening width of 2 to 100 mm.

9. The system of claim 1, wherein each of the at least two bracket pockets each have an opening height of 2 to 6 mm and an opening width of 5 to 50 mm.

10. The system of claim 1, wherein the first end of each of the at least two brackets is magnetically attracted to a corresponding each of the at least two bracket pockets.

11. The system of claim 1, wherein the first end of each of the at least two brackets is configured to connect to a corresponding each of the at least two bracket pockets via a spring-loaded detent.

12. The system of claim 1, wherein the first end of each of the at least two brackets is configured to connect to a corresponding each of the at least two bracket pockets via a snap-fit connection.

13. The system of claim 1, wherein each of the at least two brackets are configured to clamp to the computer hardware at the second end via an nutand/ora screw.

14. The system of claim 1, wherein each of the at least two brackets have a Youngs modulus of at least 2 GPa.

15. The system of claim 1, wherein, when the computer hardware contact surface is in tight contact with the computer hardware, the computer hardware contact surface is pressed towards the computer hardware with a pressure of at least 2 Pa.

16. A system for cooling computer hardware comprising:
a heat exchanger including a computer hardware contact surface configured to be in thermal contact with the computer hardware on a first side and to be in thermal contact with a cooling liquid on a second side, the second side being opposite to the first side; and
a bracket configured to removably clamp the heat exchangerto the computer hardware.

17. The system of claim 16 wherein, when removably clamping the heat exchangerto the computer hardware, the bracket extends across a widest portion of the heat exchanger.

18. The system of claim 16:
wherein the bracket is a first bracket;
wherein the system further comprises a second bracket configured to removably clamp the heatexchangerto the computer hardware.
wherein, when removably clamping the heat exchangerto the computer hardware, the first bracket and second bracket cross over each other at a middle of the heat exchanger.

19. The system of claim 16:
wherein the bracket is a first bracket;
wherein the system further comprises a second bracket configured to removably clamp the heatexchangerto the computer hardware.
wherein, when removably clamping the heat exchangerto the computer hardware, the first bracket and second bracket connect to the heatexchangerat opposite sides of the heat exchanger.

20. The system of claim 16, wherein, when the at heat exchanger is clamped to the computer hardware, the computer hardware contact surface is pressed towards the computer hardware with a pressure of at least 2 Pa.
